(19) United States
(12) Patent Application Publication
(10) Pub. No.: US 2026/0362992 A1
(43) Pub. Date: Nov. 12, 2026

(54) RECOGNITION-GUIDED TRIPLE-BAND NEAR-FIELD THERMOPHOTOVOLTAIC ENERGY-CONVERSION MODULE

(71) Applicant: Jonathan Washburn, Austin, TX (US)

(72) Inventor: Jonathan Washburn, Austin, TX (US)

(21) Appl. No.: 19/675,102

(22) Filed: May 12, 2026

Related U.S. Application Data
(60) Provisional application No. 63/804,590, filed on May 12, 2025.

(51) Int. Cl. H10N 97/00; H10F 19/50; H10F 55/155

(52) U.S. Cl. CPC H10N 97/00; H10F 19/50; H10F 55/155

(57) ABSTRACT

A near-field thermophotovoltaic energy-conversion module includes a triple-band emitter, a dynamically biased graphene spectral-control gate, a band-matched multijunction photovoltaic receiver, and a sub-wavelength vacuum gap between the emitter and the receiver. The emitter provides three discrete near-field spectral channels. The graphene spectral-control gate dynamically re-weights modal density in closed loop based on sensed emitter temperature information and photovoltaic electrical information to maintain spectral alignment during operation. The multijunction photovoltaic receiver includes sub-cells corresponding to the three discrete near-field spectral channels such that each channel has non-zero above-gap overlap with a corresponding sub-cell. The sub-wavelength vacuum gap enables evanescent transfer between the emitter and the multijunction photovoltaic receiver. In preferred implementations, the emitter comprises a hyperbolic metamaterial emitter configured for triple-band spectral response and sub-1000 K operation.

### CROSS-REFERENCE TO RELATED APPLICATIONS

This application claims the benefit of U.S. Provisional Patent Application No. 63/804,590, filed May 12, 2025, the entire disclosure of which is incorporated herein by reference.

### BACKGROUND OF THE INVENTION

The present disclosure relates generally to solid-state energy conversion and, more particularly, to near-field thermophotovoltaic systems that use a triple-band hyperbolic emitter, a dynamically biased graphene spectral-control gate, and a band-matched multijunction photovoltaic receiver to increase power density and conversion efficiency at lower emitter temperatures than prior near-field thermophotovoltaic systems. The disclosed subject matter lies at the intersection of hyperbolic metamaterial photonics, tunable graphene plasmonics, multijunction photovoltaics, and recognition-science-guided structural design.

Near-field thermophotovoltaic systems generally place a thermal emitter in close proximity to a photovoltaic receiver so that evanescent electromagnetic modes can tunnel across a sub-wavelength gap and transfer radiative energy at rates exceeding ordinary far-field blackbody transfer. In principle, this near-field regime can materially increase usable radiative coupling. In practice, however, conventional systems remain limited by spectral mismatch, thermal losses, insufficient selectivity, and instability under drift.

Existing single-junction near-field thermophotovoltaic systems suffer from substantial spectral waste because photons below the receiver bandgap are not effectively converted and photons substantially above the bandgap tend to generate excess heat through thermalization. Tandem and multijunction thermophotovoltaic systems improve bandwidth utilization to some extent, but they commonly rely on broadband emitters that distribute radiative power too broadly across the spectrum rather than selectively concentrating power at the receiver absorption regions most useful for electrical extraction. Prior hyperbolic metamaterial emitter designs may sharpen spectral behavior, but they are commonly configured around single-peak or otherwise insufficiently selective responses and are often tuned numerically rather than through the structurally guided triple-band architecture disclosed here. Prior graphene-based tuning approaches also fail to provide the disclosed combination of multiple locked spectral channels and dynamic modal re-weighting that preserves channel alignment during operation. A further practical limitation is temperature. Many prior near-field thermophotovoltaic approaches rely on emitter temperatures at or above about 1200 K, which can aggravate oxidation, creep, thermal-expansion mismatch, materials degradation, and shortened service life. Existing systems also do not provide the disclosed combination of selective triple-band concentration, dynamic graphene-based spectral stabilization, channel-matched multijunction conversion, and sub-wavelength near-field coupling in a unified architecture directed to meaningful electrical output at sub-1000 K operating conditions. In addition, prior systems do not provide the same form of formal verification support for enhancement, alignment, stability, and structural relationships as described in the present disclosure

Accordingly, a need exists for an improved near-field thermophotovoltaic architecture that reduces spectral waste, selectively concentrates radiative power into multiple useful channels, maintains channel-to-receiver alignment under thermal drift, supports lower-temperature operation, and improves useful electrical extraction without relying on the limitations of conventional broadband or single-band configurations. The present disclosure addresses these and other needs.

### SUMMARY OF THE INVENTION

The present disclosure provides, in one aspect, a near-field thermophotovoltaic energy-conversion architecture comprising a triple-band hyperbolic emitter, a dynamically biased graphene spectral-control gate, a band-matched multijunction photovoltaic receiver, and a sub-wavelength vacuum gap between the emitter and the receiver. In the disclosed architecture, the emitter, the graphene gate, the receiver, and the vacuum gap operate as a co-designed system in which three discrete near-field spectral channels are selectively coupled across the gap, dynamically maintained in alignment during operation, and converted into useful electrical output.

In preferred implementations, the emitter is configured to provide three discrete resonant spectral channels within a near-infrared operating window. In more particular preferred implementations, the three channels are centered approximately at 0.65 eV, 0.95 eV, and 1.35 eV. In the preferred disclosed emitter architecture, the three peak locations are consequences of the phi-scaled stack rather than separately tuned free parameters. In preferred implementations, the emitter comprises a multilayer hyperbolic metamaterial structure having alternating metallic and dielectric layers arranged so as to provide a preferred metal-to-dielectric fill fraction of phi\hat{ }-2, which is the preferred structurally determined and structurally optimal partition of the disclosed stack.

In preferred implementations, the graphene spectral-control gate is positioned within near-field coupling distance of the emitter and is dynamically biased to control modal coupling among the disclosed channels. In more particular preferred implementations, the graphene gate is positioned within about 10 nm of the emitter and, more preferably, is separated from the emitter by an approximately 5 nm dielectric spacer. In preferred implementations, recognition nodes are frequencies where d kappa/d E_F=0, and at such frequencies modal coupling is stationary with respect to the graphene Fermi level, thereby creating a self-stabilizing spectral lock. In preferred implementations, the graphene gate dynamically re-weights modal density at each channel to maintain spectral alignment under drift. In further preferred implementations, E_coh quantization and eight-tick control-window operation belong to the preferred RS-grounded control architecture.

In preferred implementations, the photovoltaic receiver comprises a matched triple-junction receiver corresponding to the three disclosed channels. In preferred implementations, each matched channel has non-zero above-gap overlap with the corresponding sub-cell. In particular implementations, the receiver comprises a GaSb/In0.53Ga0.47As/GaInAsSb multijunction stack, although other channel-matched receiver implementations may be used.

In preferred implementations, the emitter and the receiver are separated by a sub-wavelength vacuum gap that enables evanescent near-field transfer. In more particular implementations, the vacuum gap is about 60 nm and is maintained by support structures configured to preserve near-field coupling while limiting parasitic thermal conduction.

In preferred operating regimes, the disclosed architecture is capable of about 7.4 W/cm\hat{ }2 electrical output at an emitter temperature of about 950 K with about 37 percent conversion efficiency and about a 2.7× improvement over a comparable single-band near-field thermophotovoltaic baseline. In preferred implementations, the triple-band arrangement concentrates more than 80 percent, and preferably about 82 percent, of the relevant near-field spectral power into the disclosed channels. In preferred implementations, dynamic graphene control maintains channel-to-target misalignment within about plus or minus 10 meV and efficiency within about 2 percentage points for plus or minus 50 K emitter drift. The disclosed architecture is designed to achieve sub-1000 K operation as an architectural objective, not merely as an incidental operating condition, while maintaining spectral alignment under emitter drift through closed-loop gate-bias updates based on sensed emitter temperature information and photovoltaic electrical information.

In certain implementations, the present disclosure also provides methods of converting thermal energy to electrical energy by generating three discrete near-field spectral channels, maintaining spectral alignment among those channels and corresponding photovoltaic absorption regions through dynamic graphene bias control, coupling the channels across a sub-wavelength vacuum gap, and extracting electrical power from a matched multijunction receiver.

In certain implementations, the present disclosure further provides systems incorporating one or more disclosed modules together with heat sources, thermal-management structures, control circuitry, packaging structures, and power-conditioning circuitry.

Certain enhancement, alignment, stability, and structural propositions associated with the disclosed architecture are machine-verified in Lean 4. Other features, advantages, and aspects of the disclosure will be apparent from the following description, drawings, and claims.

### BRIEF DESCRIPTION OF THE DRAWINGS

FIG. 1 is a cross-sectional view of a preferred triple-band near-field thermophotovoltaic module showing a hyperbolic metamaterial emitter, a graphene spectral-control gate, a dielectric spacer, a vacuum gap, support pillars, a multijunction photovoltaic stack, and a heat spreader.

FIG. 2 is a spectral alignment diagram showing three emitter channels and corresponding photovoltaic sub-cell bandgaps, including overlap regions between the channels and the corresponding sub-cells.

FIG. 3 is a graph showing near-field enhancement as a function of gap width for the three spectral channels.

FIG. 4 is a graph showing conversion efficiency as a function of graphene Fermi level across a disclosed tuning range.

FIG. 5 is a graph showing power density as a function of emitter temperature for multiple gap values.

FIG. 6 is a control-system block diagram showing sensing, control, and gate-bias feedback used to maintain spectral alignment under drift.

FIG. 7 is a process-flow diagram showing fabrication of the hyperbolic metamaterial emitter, spacer architecture, graphene transfer, photovoltaic growth, bonding, and encapsulation.

FIG. 8 is a diagram of a multijunction photovoltaic stack showing three sub-cells, tunnel junctions, a carrier-collection path, and electrical output terminals.

FIG. 9 is a diagram of a vacuum-gap and spacer architecture showing pillar dimensions, pitch, coating, active-area fraction, and a thermal-leakage path.

FIG. 10 is a diagram of a near-field coupling model showing an emitter mode region 1002, an evanescent field region 1004, a graphene-controlled coupling region 1006, a receiver absorption region 1008, a first channel path 1010, a second channel path 1012, a third channel path 1014, and a suppressed waste-heat path 1016.

FIG. 11 is a diagram of an industrial waste-heat recovery deployment using one or more disclosed modules coupled to a hot-side source and a cooled photovoltaic-side assembly.

FIG. 12 is a diagram of technically adjacent alternative module configurations including alternative emitter-material configurations, alternative receiver-material configurations, alternative gap configurations, alternative support structures, and optional patterned-surface configurations.

### DETAILED DESCRIPTION OF THE INVENTION

The present disclosure is directed to a near-field thermophotovoltaic energy-conversion architecture that is not merely a generic near-field thermophotovoltaic arrangement, not merely a generic multijunction thermophotovoltaic arrangement, and not merely a generic graphene-tuning arrangement. Rather, the disclosed subject matter provides a co-designed triple-band, dynamically stabilized, band-matched near-field energy-conversion architecture in which a triple-band hyperbolic emitter, a dynamically biased graphene spectral-control gate, a matched multijunction photovoltaic receiver, and a sub-wavelength vacuum gap cooperate as a unified operating structure to improve useful electrical extraction from thermal energy at lower emitter temperatures than conventional systems.

In the disclosed architecture, the emitter provides three discrete near-field spectral channels, the graphene gate creates a self-stabilizing spectral lock and dynamically re-weights modal coupling under drift, the receiver selectively converts the matched channels, and the vacuum gap enables evanescent transfer between the emitter and the receiver. These components are preferably configured as a co-designed emitter/gate/receiver/gap architecture.

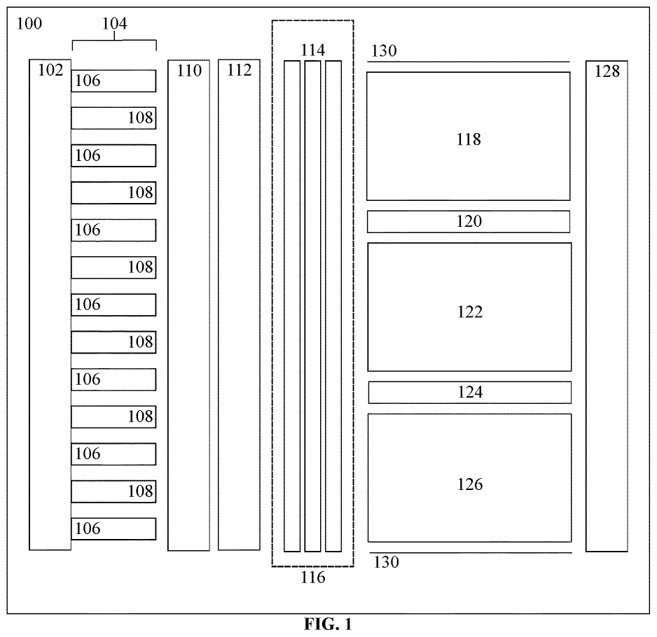

Referring now to FIG. 1, a preferred module 100 includes a backplane 102, an emitter 104 supported by the backplane 102, a dielectric spacer 110, a graphene gate 112, a vacuum gap 114, one or more support pillars 116 extending across the vacuum gap 114, a top photovoltaic sub-cell 118, an upper tunnel junction 120, a middle photovoltaic sub-cell 122, a lower tunnel junction 124, a bottom photovoltaic sub-cell 126, a heat spreader 128, and output contacts 130. In preferred implementations, the emitter 104 comprises a multilayer hyperbolic metamaterial structure including alternating metallic layers 106 and dielectric layers 108 arranged to provide a triple-band spectral response. The backplane 102 preferably provides thermal conduction, structural support, and optical reflection functions. The dielectric spacer 110 preferably electrically isolates the graphene gate 112 from the emitter 104 while maintaining sufficient proximity for near-field spectral control. The vacuum gap 114 is preferably maintained at a sub-wavelength dimension such that evanescent electromagnetic coupling occurs between the emitter 104 and the photovoltaic sub-cells 118, 122, 126. The support pillars 116 preferably maintain mechanical spacing while limiting parasitic thermal conduction. The heat spreader 128 preferably removes heat from the photovoltaic side of the module 100. The output contacts 130 provide electrical connection for extracting generated electrical power.

In preferred implementations, thermal energy is delivered to the emitter 104 from a suitable heat source such that the emitter 104 produces three discrete resonant spectral channels within an operative near-infrared range. The graphene gate 112 is biased to dynamically control modal coupling associated with those channels. Radiative transfer across the vacuum gap 114 is dominated by near-field coupling rather than ordinary far-field transfer, and the receiver structure formed by the photovoltaic sub-cells 118, 122, 126 is selected so that the three channels are matched to corresponding receiver absorption regions. In this manner, the disclosed module 100 operates as an integrated spectral-concentration and spectral-conversion device rather than as a simple emitter positioned adjacent to a generic photovoltaic receiver.

In preferred embodiments, the disclosed architecture is expressly triple-band in character. The three-channel arrangement is not incidental. Rather, the disclosed architecture uses three discrete near-field channels as a load-bearing structural and operational feature. In preferred implementations, the emitter is configured to generate channels centered approximately at 0.65 eV, 0.95 eV, and 1.35 eV, and the graphene gate 112 is configured to maintain spectral alignment of those channels under operating drift.

In preferred implementations, the module 100 further includes sensing and control structures, whether integrated on-chip, disposed at a package level, or implemented in associated electronics, to monitor one or more operating conditions and adjust bias applied to the graphene gate 112. Such operating conditions may include emitter temperature, photovoltaic current, photovoltaic voltage, current-voltage behavior, or combinations thereof. In preferred implementations, sensed operating information is used in closed loop to update gate bias, preserve spectral alignment among the three disclosed channels and the corresponding photovoltaic sub-cells, and reduce maximum channel-to-target misalignment during drift in emitter temperature, load condition, or related operating variables.

In some implementations, packaging structures, vacuum enclosures, getters, control electronics, power-conditioning circuitry, cooling loops, and mounting structures may also be provided. These additional structures may facilitate operation, manufacturability, durability, or deployment, but do not alter the core architecture in which the emitter 104, the graphene gate 112, the receiver formed by the photovoltaic sub-cells 118, 122, 126, and the vacuum gap 114 cooperate to provide the disclosed triple-band, dynamically stabilized, near-field thermophotovoltaic conversion mechanism.

In preferred implementations, the disclosed architecture supports sub-1000 K operation. By concentrating radiative power into the disclosed channels, dynamically preserving spectral alignment under drift, and matching those channels to a multijunction receiver across a sub-wavelength vacuum gap 114, the disclosed module 100 improves useful channel-selective extraction relative to conventional single-band or broadband near-field thermophotovoltaic systems.

The following description sets forth preferred emitter structures, preferred graphene-control structures, preferred receiver structures, preferred gap-support structures, preferred near-field transfer mechanisms, preferred control workflows, preferred fabrication approaches, preferred modeled embodiments, and technically adjacent alternatives. Unless otherwise indicated, references to preferred implementations are intended to illustrate the disclosed architecture and not to limit the scope of the claims.

In preferred implementations, the emitter 104 is a multilayer hyperbolic metamaterial emitter configured to provide three discrete resonant spectral channels within an operative near-infrared energy range. The emitter 104 preferably includes alternating metallic layers 106 and dielectric layers 108 disposed over the backplane 102 so as to establish an anisotropic effective medium exhibiting hyperbolic dispersion over a selected operating band. The backplane 102 preferably serves as a thermal conductor, a structural support, and a reflector that cooperates with the multilayer stack to define the spectral behavior of the emitter 104.

In preferred implementations, the emitter 104 is designed from selected layer materials, selected layer thicknesses, a selected multilayer period, and a selected metal-to-dielectric fill fraction so as to provide a triple-band response rather than a broadband response or a single-peak response. Thermal energy received from an associated heat source is converted by the emitter 104 into spectrally concentrated radiative output in three discrete channels, and the emitter 104 further provides an enhanced photonic density of states that supports strong near-field coupling across the vacuum gap 114. In preferred implementations, the emitter 104 is configured so that a substantial fraction of the relevant near-field spectral power is concentrated into the three disclosed channels.

In preferred implementations, the effective-medium behavior of the emitter 104 may be described in plain-text form as follows: epsilon_parallel(omega)=f×epsilon_metal(omega)+(1−f)×epsilon_dielectric(omega) 1/epsilon_perpendicular(omega)=f/epsilon_metal(omega)+(1−f)/epsilon_dielectric(omega)

where f is the metal fill fraction, epsilon_metal(omega) is the frequency-dependent permittivity of the selected metallic layer material, and epsilon_dielectric(omega) is the frequency-dependent permittivity of the selected dielectric layer material. In preferred implementations, the multilayer stack is selected such that epsilon_parallel and epsilon_perpendicular have opposite signs over an operative energy band, thereby producing a hyperbolic region that supports the disclosed resonant channel behavior.

In preferred implementations, the preferred disclosed metal-to-dielectric fill fraction is phi\hat{ }-2 and is the preferred structurally determined and structurally optimal partition of the disclosed stack. In preferred implementations, phi\hat{ }-2 is equal to 2-phi, where phi is the positive solution of phi\hat{ }-2=phi+1. In preferred implementations, the three peak locations are consequences of the phi-scaled stack rather than separately tuned free parameters. Thus, in the preferred disclosed emitter architecture, the triple-band response is not produced merely by ad hoc numerical fitting of unrelated peaks, but instead follows from the disclosed structural selection of the multilayer geometry and material partition. In preferred RS-grounded implementations, the disclosed partition and channel ordering are further associated with J-cost optimality, E_coh=phi\hat{ }-5 quantization, and eight-tick phase structure as part of the preferred structural basis of the emitter architecture.

In preferred implementations, the operative hyperbolic band spans approximately 0.5 eV to 1.5 eV, and the emitter 104 is configured so that finite-stack resonance behavior produces three preferred resonant channels centered approximately at 0.65 eV, 0.95 eV, and 1.35 eV. Expressed in wavelength terms, these preferred channels correspond approximately to 1.91 um, 1.31 um, and 0.92 um, respectively. In preferred implementations, these three channels concentrate more than 80 percent, and preferably about 82 percent, of the relevant near-field spectral power into the disclosed channels.

In one preferred implementation, the emitter 104 comprises a titanium nitride and aluminum oxide multilayer stack supported by a molybdenum backplane 102. In a more particular preferred implementation, the emitter 104 comprises seven periods of alternating titanium nitride metallic layers 106 and aluminum oxide dielectric layers 108. In a still more particular preferred implementation, each titanium nitride layer 106 has a thickness of about 23 nm, each aluminum oxide layer 108 has a thickness of about 37 nm, the multilayer period is about 60 nm, and the total multilayer thickness is about 420 nm. In preferred implementations, this arrangement provides a structurally determined triple-band emitter implementation centered on the disclosed channels.

In preferred implementations, the metallic layers 106 may be selected from refractory or plasmonically suitable materials including titanium nitride, hafnium nitride, zirconium nitride, tantalum nitride, tungsten, or combinations thereof. The dielectric layers 108 may be selected from aluminum oxide, silicon dioxide, magnesium fluoride, hafnium oxide, silicon nitride, or combinations thereof. Although the titanium nitride/aluminum oxide/molybdenum configuration is presently preferred, other material combinations may be used provided that the resulting multilayer structure preserves the disclosed triple-band hyperbolic-emitter logic and remains technically adjacent to the disclosed near-field thermophotovoltaic architecture. In preferred implementations, the number of periods, individual layer thicknesses, total stack thickness, and selected material combination may be varied to preserve the disclosed triple-band near-field response. Likewise, alternative multilayer periods, alternative fill fractions near the preferred disclosed partition, and alternative refractory support structures may be employed where suitable for a given operating target. However, in preferred implementations, the disclosed emitter 104 remains centered on a triple-band hyperbolic multilayer architecture configured to provide three discrete channels that are matched to a corresponding multijunction receiver architecture.

In preferred implementations, the emitter 104 is also characterized by enhanced photonic density of states and associated Purcell enhancement. For example, at representative operating wavelengths near the center of the preferred band, the multilayer period is substantially below one-half wavelength, and the resulting Purcell factor may be estimated in plain-text form as: F_P=(lambda/2 Lambda)\hat{ }2 where lambda is a representative channel wavelength and Lambda is the multilayer period. In a preferred implementation using a period of about 60 nm and a representative wavelength near 1.3 um, the Purcell factor is greater than unity and may be on the order of about 10\hat{ }2, thereby supporting strong selective enhancement of the disclosed channels.

In some implementations, the exposed emitter surface may additionally include technically adjacent patterning or texturing features, including optional chi-lattice patterned-surface configurations, provided that such features remain subordinate to and consistent with the disclosed triple-band hyperbolic-emitter architecture. Such patterned-surface configurations are optional enhancements rather than required elements of the core module architecture.

Accordingly, the emitter 104 is preferably configured as a structurally guided triple-band hyperbolic emitter that generates three discrete near-field channels for selective coupling across the vacuum gap 114.

In preferred implementations, the graphene gate 112 is positioned proximate the emitter 104 and is configured to provide dynamic spectral control of the disclosed channels. The graphene gate 112 is preferably a monolayer graphene structure disposed above the upper surface of the emitter 104 and separated from the emitter 104 by the dielectric spacer 110. In preferred implementations, the graphene gate 112 is electrically coupled to a bias source through peripheral contacts and is operated so that changes in gate bias produce corresponding changes in graphene Fermi level and modal coupling behavior.

In preferred implementations, the graphene gate 112 is positioned within near-field coupling distance of the emitter 104, preferably within about 10 nm of the emitter 104 and, more preferably, at a spacing of about 5 nm as defined by the dielectric spacer 110. The dielectric spacer 110 may comprise aluminum oxide or another suitable dielectric material that electrically isolates the graphene gate 112 from the emitter 104 while preserving the close spacing used for spectral control. In preferred implementations, the graphene gate 112, the dielectric spacer 110, and the emitter 104 cooperate as a spectral-control assembly through which the emitted near-field channels may be tuned, stabilized, and dynamically re-weighted during operation.

In preferred implementations, the intra-band conductivity of the graphene gate 112 may be described in plain-text form as follows: sigma_intra(omega)=(2 e\hat{ }2 k_B T)/(pi hbar\hat{ }2)×(i/(omega+i gamma_g))×ln(2 cosh(E_F/2 k_B T)) where E_F is the graphene Fermi level and gamma_g is a graphene scattering term. In preferred implementations, modulation of E_F changes the optical response of the graphene gate 112 and thereby changes the manner in which the graphene gate 112 interacts with evanescent modes generated by the emitter 104.

In preferred implementations, recognition nodes are frequencies where d kappa/d E_F=0. At these frequencies, modal coupling is stationary with respect to the graphene Fermi level, thereby creating a self-stabilizing spectral lock. In preferred implementations, the graphene gate 112 dynamically re-weights modal density at each channel to maintain spectral alignment under drift. Thus, the graphene gate 112 is not merely a passive overlayer or a generic tunable film, but instead functions as a dynamically biased spectral-control structure that preserves useful channel alignment under changing operating conditions.

In preferred implementations, the graphene gate 112 is biased over a preferred Fermi-level range of about 0.28 eV to about 0.48 eV. In preferred implementations, this tuning range permits the disclosed recognition-node conditions to be positioned relative to the three preferred channels so that channel-specific coupling may be maintained even as emitter temperature shifts or other operating conditions vary. In preferred implementations, the graphene gate 112 is configured to maintain alignment of the disclosed channels within about plus or minus 10 meV relative to corresponding photovoltaic absorption targets.

In preferred implementations, the dynamic function of the graphene gate 112 may be understood as follows. Emitter drift, including thermal drift, may shift the effective spectral output of the emitter 104. In response, the bias applied to the graphene gate 112 is adjusted so as to preserve overlap between the three disclosed channels and the corresponding receiver absorption regions. The control objective is preferably to maximize useful overlap between each channel and the corresponding sub-cell, suppress sub-band waste heat, reduce excess thermalization losses, and preserve total useful electrical extraction. In preferred implementations, tie-break priorities are ordered such that non-zero above-gap overlap is preserved for all three matched channels first, thermalization and sub-band leakage are reduced second, and total useful electrical extraction is preserved or increased third. In preferred RS-grounded implementations, the ordering of these control priorities is further associated with reciprocity, E_coh-quantized extraction, and eight-tick control-window operation as preferred control-architecture features.

In preferred implementations, sensing information used to control the graphene gate 112 may include emitter temperature information, photovoltaic output information, or both. For example, temperature-only sensing may be used in some implementations, photovoltaic-output-only sensing may be used in some implementations, and combined emitter-temperature and photovoltaic-output sensing may be used in preferred implementations. Photovoltaic-output sensing may include short-circuit current, open-circuit voltage, full current-voltage behavior, or combinations thereof. In preferred implementations, combined sensing with closed-loop bias control is the preferred disclosed implementation, with sensed emitter temperature information and photovoltaic electrical information used together to update gate bias.

In preferred implementations, control of the graphene gate 112 may be temperature-responsive, photovoltaic-output-responsive, or responsive to a combination of emitter temperature and photovoltaic output. In preferred implementations, the control arrangement is closed-loop and preserves spectral alignment under emitter drift by repeatedly sensing emitter temperature information and photovoltaic electrical information, determining a current spectral-alignment error, computing a revised gate setting, applying the revised bias to the graphene gate 112, and confirming stabilized or improved electrical output. In some implementations, stored calibration values, computed channel targets, or both may be used in determining updated bias settings.

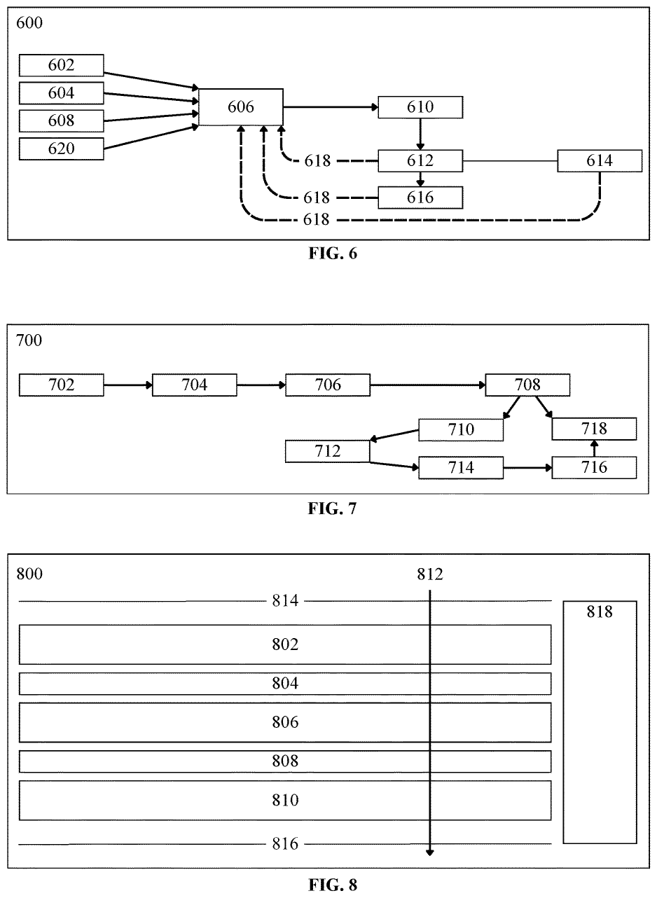

Referring also to FIG. 6, a preferred control system 600 may include a temperature sensor 602, a photovoltaic electrical monitor 604, a controller 606, optional calibration memory 608, a bias output stage 610, the graphene gate 612, an emitter 614, a photovoltaic stack 616, one or more feedback signal paths 618, and an optional control-window scheduler 620. In preferred implementations, the temperature sensor 602 may comprise a thin-film resistive temperature detector coupled to the emitter side of the module, and the photovoltaic electrical monitor 604 may measure current, voltage, power, or current-voltage characteristics of the photovoltaic stack 616. The controller 606 uses the sensed information to determine a current spectral-alignment error and to select an updated bias command applied through the bias output stage 610 to the graphene gate 612, preferably by preserving non-zero above-gap overlap for all three matched channels and reducing a maximum channel-to-target misalignment.

In preferred implementations, a preferred bias law may be expressed in plain-text form as follows: Delta E_F=−alpha×Delta T×(k_B/E_channel) where alpha is a gain coefficient and E_channel is a selected channel energy or channel-reference value. In preferred implementations, alpha is about 0.8, although other gain values may be used depending on calibration, architecture, or operating regime. In preferred implementations, this bias law is used to compensate for drift in emitter temperature and preserve channel-to-receiver alignment by reducing a maximum channel-to-target misalignment across the three disclosed channels.

In preferred implementations, the disclosed control architecture maintains alignment stability, efficiency-band stability, temperature-drift stability, and misalignment stability. More particularly, dynamic bias preferably maintains channel alignment, maintains efficiency within a preferred operating band, preserves performance under plus or minus 50 K drift, and maintains misalignment within about plus or minus 10 meV. In preferred implementations, efficiency is retained within about 2 percentage points across the preferred drift range.

In preferred implementations, reciprocity, E_coh-quantized extraction, and eight-tick control-window operation belong to the preferred RS-grounded control architecture. These features may be used in preferred implementations to define control timing, acceptance of extraction events, synchronization of control windows, or related operating logic. However, the graphene gate 112 remains load-bearing in the disclosed architecture because it provides the dynamic spectral-control and modal re-weighting function that preserves the usefulness of the three-channel architecture under drift.

In preferred implementations, the graphene gate 112 and associated control structures preserve spectral alignment and useful electrical extraction over changing operating conditions.

In preferred implementations, the receiver portion of the module 100 comprises a multijunction photovoltaic structure configured to selectively convert the three disclosed channels into electrical output. As shown in FIG. 1 and FIG. 8, the receiver may include the top photovoltaic sub-cell 118, the middle photovoltaic sub-cell 122, the bottom photovoltaic sub-cell 126, associated tunnel junctions 120 and 124, output contacts 130 or, in the FIG. 8 arrangement, a photovoltaic stack 800 including a top sub-cell 802, a first tunnel junction 804, a middle sub-cell 806, a second tunnel junction 808, a bottom sub-cell 810, a current path 812, front and back contacts 814 and 816, and a heat-removal path 818. In preferred implementations, the receiver is configured as a band-matched receiver, more particularly as a channel-corresponding receiver, and more particularly as a receiver in which each matched channel has non-zero above-gap overlap with the corresponding sub-cell.

In preferred implementations, the receiver is a matched triple-junction receiver corresponding to the three disclosed channels. In preferred implementations, the receiver comprises three sub-cells connected in series through tunnel junctions such that absorbed photon energy is converted into electrical current and voltage at a combined output. Photons transferred across the vacuum gap 114 are selectively absorbed in the corresponding sub-cells, charge carriers are generated in the sub-cells, the carriers pass through the tunnel junctions, and electrical output is collected through associated contacts. In preferred implementations, the acceptance criterion for the receiver is that each matched channel has non-zero above-gap overlap with the corresponding sub-cell.

In one preferred implementation, the bottom photovoltaic sub-cell 126 comprises gallium antimonide, the middle photovoltaic sub-cell 122 comprises indium gallium arsenide, and the top photovoltaic sub-cell 118 comprises gallium indium arsenide antimonide. In a more particular preferred implementation, the receiver is a GaSb/In0.53Ga0.47As/GaInAsSb triple-junction receiver. In preferred implementations, these materials provide preferred receiver bandgaps of about 0.71 eV, about 0.94 eV, and about 1.34 eV, respectively, and are arranged so that the disclosed channels correspond to the disclosed sub-cells.

In preferred implementations, channel-to-sub-cell alignment may be described as follows. A first channel centered near about 0.65 eV corresponds to the bottom photovoltaic sub-cell 126 having a bandgap near about 0.71 eV. Although the center of the first channel may lie below the nominal bandgap value, the spectral support of that channel extends above the bandgap so that non-zero above-gap overlap is present. A second channel centered near about 0.95 eV corresponds to the middle photovoltaic sub-cell 122 having a bandgap near about 0.94 eV. A third channel centered near about 1.35 eV corresponds to the top photovoltaic sub-cell 118 having a bandgap near about 1.34 eV. Thus, in preferred implementations, alignment means each matched channel has non-zero above-gap overlap with the corresponding sub-cell and does not require every channel center to lie above the corresponding bandgap.

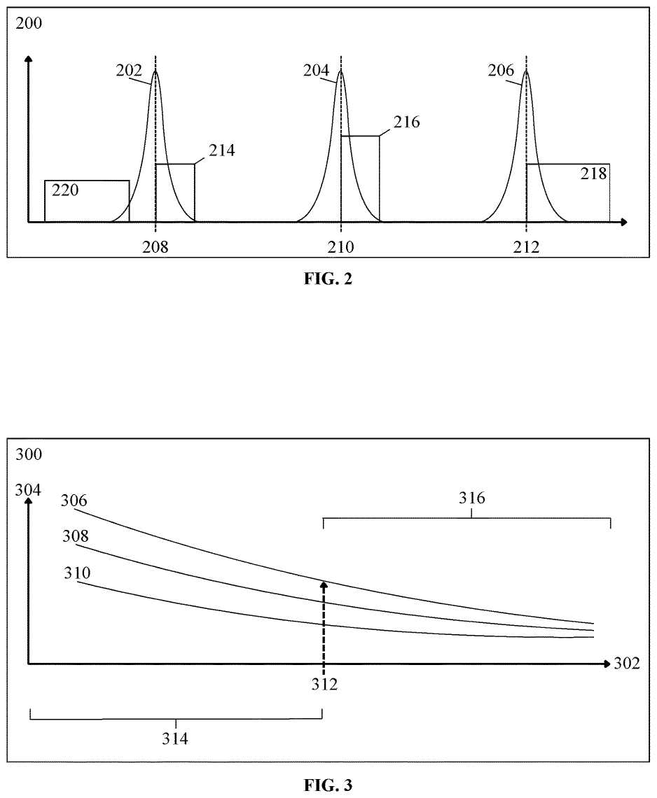

Referring to FIG. 2, a spectral alignment plot 200 may include a first channel 202, a second channel 204, a third channel 206, a first sub-cell edge 208, a second sub-cell edge 210, a third sub-cell edge 212, overlap regions 214, 216, and 218, and a suppressed sub-band region 220. In preferred implementations, the overlap regions 214, 216, and 218 represent the useful portions of the three channels that contribute to carrier generation in the corresponding sub-cells, while the suppressed sub-band region 220 corresponds to spectral content that is reduced, avoided, or deprioritized by the disclosed emitter and graphene-control architecture.

In preferred implementations, the receiver sub-cells have thicknesses and conversion characteristics selected to support the disclosed architecture. For example, in one preferred implementation, the bottom photovoltaic sub-cell 126, the middle photovoltaic sub-cell 122, and the top photovoltaic sub-cell 118 each have thicknesses on the order of about 2 um. In preferred implementations, the sub-cells may exhibit external quantum efficiencies of about 0.88, about 0.91, and about 0.87, respectively, although other values may be used. In preferred implementations, the tunnel junctions 120 and 124 are configured to provide series interconnection with limited voltage loss, for example combined tunnel-junction losses on the order of about 70 mV.

In preferred implementations, current generated by the top photovoltaic sub-cell 118, the middle photovoltaic sub-cell 122, and the bottom photovoltaic sub-cell 126 is collected through associated contact structures and delivered to an external circuit through the output contacts 130. The heat spreader 128 and related cooling structures may be used to remove heat from the receiver side of the module 100 and to preserve preferred photovoltaic operating temperature. In preferred implementations, the receiver is maintained near about 320 K while the emitter is operated at a substantially higher temperature.

In broader implementations, the receiver may be described as a band-matched receiver. In narrower implementations, the receiver may be described as a channel-corresponding receiver in which each matched channel has non-zero above-gap overlap with the corresponding sub-cell. In preferred implementations, the receiver is a matched triple-junction receiver, and in a presently preferred implementation the receiver is a GaSb/In0.53Ga0.47As/GaInAsSb receiver. This hierarchy is intended to preserve the load-bearing matching relationship while also supporting narrower material-specific embodiments.

In some implementations, alternative receiver structures may be used provided that they preserve the disclosed matching relationship between the three channels and the receiver absorption structure. Thus, alternative III-V alloy systems, alternative bandgap selections, alternative multijunction stacks, and alternative current-collection arrangements may be used. However, in preferred implementations, the receiver remains a matched triple-junction photovoltaic receiver corresponding to the three disclosed channels and configured so that each matched channel has non-zero above-gap overlap with the corresponding sub-cell.

Accordingly, the receiver side of the disclosed module is not merely a generic photovoltaic absorber. Rather, it is a co-designed multijunction receiver architecture matched to the triple-band emitter and dynamically stabilized graphene gate so that the three disclosed channels may be selectively converted into useful electrical output.

In preferred implementations, the emitter 104 and the receiver are separated by the vacuum gap 114, which is maintained at a sub-wavelength dimension sufficient to support near-field radiative transfer dominated by evanescent modes. The vacuum gap 114 is preferably defined and maintained by one or more support pillars 116 or related support structures that preserve spacing while limiting parasitic thermal conduction. In preferred implementations, the vacuum gap 114 is not merely a mechanical separation. Rather, it is a load-bearing part of the disclosed architecture because the disclosed transfer mechanism relies on near-field coupling across the gap 114.

In preferred implementations, the gap architecture may be characterized by a desired gap width, mechanical support requirements, and thermal leakage tolerance. The output of the gap architecture is a mechanically maintained sub-wavelength vacuum gap with acceptable parasitic conduction and preserved near-field operation. In preferred implementations, the acceptance criteria for the gap architecture are that the gap remains sufficiently small to preserve near-field transfer and that parasitic thermal conduction through the support structures remains subordinate to the desired radiative transfer mechanism.

In preferred implementations, the vacuum gap 114 is within a preferred range of about 40 nm to about 80 nm and, more preferably, is about 60 nm. In preferred implementations, the support pillars 116 have a preferred diameter of about 50 nm, a preferred pitch of about 400 nm, and a preferred height corresponding to the gap dimension. In preferred implementations, the support pillars 116 are coated with a dielectric material to reduce electrical shorting and undesired conduction effects. For example, a support pillar 116 may include a coating corresponding to the dielectric spacer material or another dielectric passivation layer.

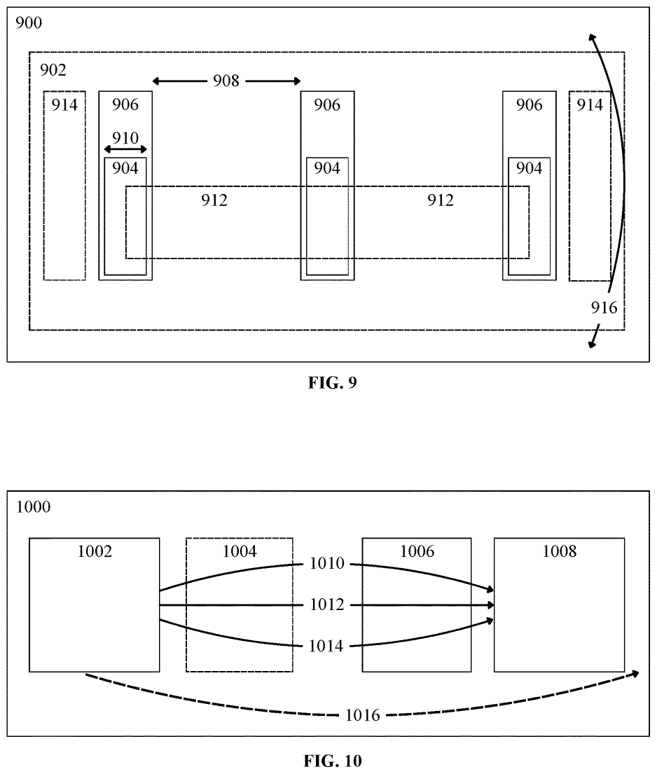

Referring also to FIG. 9, a gap architecture 900 may include the gap 902, one or more pillars 904, a pillar coating 906, a pillar pitch 908, a pillar diameter 910, an active-area region 912, an edge-support region 914, and one or more thermal-leakage paths 916. In preferred implementations, the support structures are arranged so that most of the active transfer area is preserved for radiative coupling, while mechanical support may be concentrated at selected support regions or otherwise distributed to balance structural and thermal requirements.

In preferred implementations, the support-pillars 116 occupy less than about 5 percent of the active area and, more preferably, occupy on the order of about 1 to 2 percent of the active area. In preferred implementations, the area fraction is selected so that parasitic conduction remains limited relative to the disclosed near-field radiative transfer. Support-pillar materials may include silicon nitride, silicon dioxide, or other suitable materials that provide structural integrity with acceptable thermal characteristics. In preferred implementations, the support pillars 116 comprise silicon nitride with a dielectric coating, although alternative support structures may be used.

In preferred implementations, the near-field operating regime is satisfied where the gap dimension is substantially less than the operative channel wavelength. The disclosed module therefore uses the vacuum gap 114 to support evanescent transport between the emitter 104 and the receiver. Photon transport in this regime is dominated by modes having large transverse wavevector components relative to far-field propagation, and channel-specific transmission windows may approach strong transmission near the disclosed resonances.

In preferred implementations, the spectral near-field heat flux may be described in plain-text form as follows: q(omega)=(¼ pi\hat{ }2)×T(omega, k_parallel)×[Theta(omega, T_e)−Theta(omega, T_pv)]×k_parallel d k_parallel Theta(omega, T)=hbar omega/(exp(hbar omega/k_B T)-1) where T(omega, k_parallel) is a transmission-related term, T_e is emitter temperature, and T_pv is photovoltaic temperature. In preferred implementations, integration over relevant wavevector components and energy ranges yields total heat flux dominated by the disclosed resonant channels.

In preferred implementations, the near-field enhancement may be approximated in plain-text form as: F_NF=(lambda/2 pi d)\hat{ }2 where lambda is a representative channel wavelength and d is the gap width. For a preferred gap near about 60 nm and representative channel wavelengths of about 1.91 um, 1.31 um, and 0.92 um, channel-specific near-field enhancement factors are on the order of about 26, about 12, and about 6, respectively. In preferred implementations, the disclosed channel-specific near-field enhancement works together with the Purcell enhancement of the emitter architecture to provide a combined enhancement supporting selective transfer of the three disclosed channels. In preferred implementations, validation of the disclosed enhancement includes confirming that d<lambda/2 pi for the relevant portions of the disclosed channels, confirming that Lambda<lambda/2 for the emitter multilayer period, and confirming that the disclosed triple-band architecture exceeds a comparable single-band baseline in useful channel-selective extraction.

Referring also to FIG. 3, an enhancement plot 300 may include a gap axis 302, an enhancement axis 304, a first channel curve 306, a second channel curve 308, a third channel curve 310, a nominal operating point 312, a tighter-gap region 314, and a wider-gap region 316. In preferred implementations, the plot 300 illustrates that enhancement generally increases as the gap decreases and that the disclosed channels may exhibit differing enhancement behavior across representative gap values. In preferred implementations, the nominal operating point 312 corresponds to a preferred gap near about 60 nm. Referring also to FIG. 10, a coupling model 1000 may include an emitter mode region 1002, an evanescent field 1004 extending across the vacuum gap, a graphene-controlled coupling region 1006, a receiver absorption region 1008, a first channel path 1010, a second channel path 1012, a third channel path 1014, and a suppressed waste-heat path 1016. In preferred implementations, FIG. 10 illustrates selective transfer of the disclosed near-field channels from the emitter toward the matched receiver in the presence of graphene-based dynamic coupling control, while also illustrating suppression of undesired waste-heat transfer paths. In FIG. 10, the suppressed waste-heat path 1016 represents a transfer path that is reduced relative to the channel paths 1010, 1012, and 1014 by the graphene-controlled coupling region 1006.

These validation concepts may be used in modeling, design selection, formal verification, or related support activities.

In some implementations, the gap may be narrower than the preferred nominal value, for example about 40 nm, to increase near-field enhancement and channel transfer strength. In some implementations, the gap may be broader than the preferred nominal value, for example about 80 nm or about 100 nm, while still preserving useful operation with reduced power density. In some implementations, alternative support architectures may be used, including edge-supported structures, distributed nanoscale supports, suspended structures, or related gap-maintenance arrangements. In some implementations, optional variable-gap or thermally switchable arrangements may also be employed, including microelectromechanical gap-adjustment structures, provided that such arrangements remain technically adjacent to and subordinate to the disclosed core module architecture.

Accordingly, the vacuum gap 114 and associated support structures are preferably configured not merely to hold the emitter and receiver apart, but to establish and preserve the sub-wavelength near-field transfer regime on which the disclosed triple-band, dynamically stabilized energy-conversion architecture depends.

In preferred implementations, the disclosed module includes a control workflow configured to preserve spectral alignment among the emitter 104, the graphene gate 112, and the receiver during operation. In preferred implementations, the control workflow receives emitter temperature information, photovoltaic electrical information, or both, determines a current spectral-alignment error, computes an updated graphene-bias setting to preserve non-zero above-gap overlap and reduce maximum channel-to-target misalignment, applies the updated bias, and confirms stabilized or improved electrical output. In preferred implementations, the control workflow is implemented as a closed-loop process that continuously or periodically adjusts the graphene gate 112 so that the three disclosed channels remain usefully aligned with the corresponding sub-cells, preserve non-zero above-gap overlap, and reduce maximum channel-to-target misalignment.

In preferred implementations, the control workflow may proceed through a sequence in which emitter temperature is sensed, photovoltaic electrical response is sensed, a current spectral-alignment error is determined, a revised gate setting is computed, the revised gate bias is applied, and resulting module behavior is evaluated. In some implementations, this process may include a refinement stage in which gain values, target values, stored calibration values, or combinations thereof are adjusted during calibration or operation. In preferred implementations, the acceptance criteria for the control workflow are that a spectral-alignment error, defined as a maximum absolute offset between the three disclosed channels and corresponding photovoltaic absorption targets, remains below a preferred threshold, that useful electrical performance remains within a preferred stability band, that misalignment is maintained within about plus or minus 10 meV, and that efficiency is retained within about 2 percentage points across the preferred drift range. In preferred implementations, the control architecture maintains alignment stability, efficiency-band stability, temperature-drift stability, and misalignment stability. More particularly, dynamic bias preferably maintains channel alignment, maintains efficiency within a preferred operating band, preserves performance under plus or minus 50 K drift, and maintains misalignment within about plus or minus 10 meV. In preferred implementations, efficiency is retained within about 2 percentage points across the preferred drift range. Thus, the disclosed control architecture does not merely tune the graphene gate 112 at an initial operating point, but dynamically preserves the usefulness of the three-channel architecture as operating conditions change.

In preferred implementations, the disclosed control architecture may also employ a preferred scheduler or timing arrangement under which control updates are applied in repeated windows. In preferred RS-grounded implementations, reciprocity, E_coh-quantized extraction, and eight-tick control-window operation belong to the preferred control architecture. These features may be used to define preferred timing, event acceptance, balancing, or synchronization logic in repeated control windows. In preferred implementations, however, the core practical function remains that the graphene gate 112 dynamically re-weights modal density at each channel to maintain spectral alignment under drift.

In preferred implementations, the disclosed module is configured to operate at a nominal thermal-electrical operating point in which the emitter temperature is about 950 K, the photovoltaic temperature is about 320 K, and the vacuum gap 114 is about 60 nm. Under such preferred modeled conditions, the first channel may contribute about 2.0 W/cm\hat{ }2, the second channel may contribute about 3.2 W/cm\hat{ }2, and the third channel may contribute about 2.2 W/cm\hat{ }2, for a total electrical output on the order of about 7.4 W/cm\hat{ }2. In preferred modeled validation, these channel contributions correspond to approximately 27 percent, 43 percent, and 30 percent, respectively, of the total electrical output. These values are preferred modeled or benchmarked values and are not required operating limits of the disclosure.

In preferred implementations, current-voltage behavior corresponding to the disclosed operating point may include a maximum-power-point current on the order of about 4.6 A/cm\hat{ }2 and a maximum-power-point voltage on the order of about 1.61 V, yielding electrical power on the order of about 7.4 W/cm\hat{ }2. In preferred implementations, the receiver formed by the three sub-cells provides a combined voltage contribution reduced by tunnel-junction losses and resistive losses, while still preserving useful power extraction at the disclosed operating point.

In preferred implementations, the total near-field radiative flux delivered to the receiver is on the order of about 20 W/cm\hat{ }2, and electrical output is on the order of about 7.4 W/cm\hat{ }2, corresponding to a preferred modeled conversion efficiency of about 37 percent. In broader implementations, efficiencies of at least about 30 percent may be achieved. In preferred implementations, efficiencies of at least about 35 percent may be achieved. In a preferred nominal implementation, efficiency is about 37 percent.

In preferred implementations, the disclosed module exceeds a comparable single-band near-field thermophotovoltaic baseline. For example, a comparable single-band system centered around a single channel may capture only about 38 percent of relevant spectral power and produce materially lower output, while the disclosed triple-band architecture concentrates more than 80 percent, and preferably about 82 percent, of the relevant near-field spectral power into the disclosed channels and provides about a 2.7× electrical-output improvement relative to a comparable single-band baseline. In preferred implementations, this comparative advantage results from the combined action of the structurally determined triple-band emitter, the dynamic graphene-based spectral locking and modal re-weighting, the matched triple-junction receiver, and the sub-wavelength near-field coupling across the vacuum gap 114.

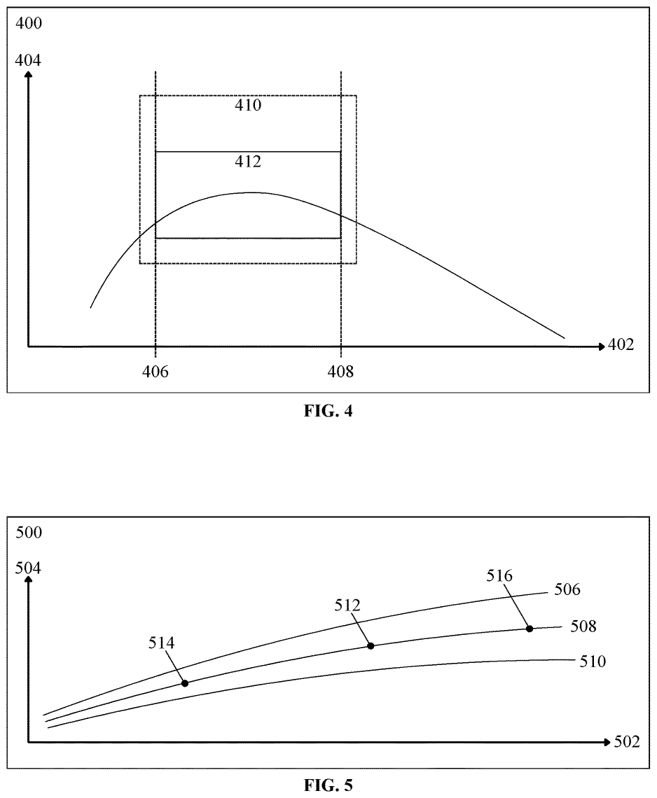

Referring also to FIG. 4, a tuning plot 400 may include a Fermi-level axis 402, an efficiency axis 404, a lower bound 406 of a preferred tuning range, an upper bound 408 of the preferred tuning range, a stability plateau 410, and a nominal operating point 412. In preferred implementations, the plot 400 shows that the disclosed tuning range of the graphene gate 112 maintains useful efficiency behavior over a defined operating region and supports drift compensation across the preferred bias range.

Referring also to FIG. 5, a power plot 500 may include a temperature axis 502, a power axis 504, a first gap curve 506, a nominal gap curve 508, a wider-gap curve 510, a nominal operating point 512, a reduced-temperature point 514, and a high-temperature point 516. In preferred implementations, the plot 500 illustrates that power density varies with emitter temperature and gap width and that the disclosed architecture maintains useful operation in a sub-1000 K regime.

In preferred implementations, the technical effects and advantages of the disclosed architecture include higher useful electrical extraction, improved spectral selectivity, improved stability under drift, and meaningful operation at lower emitter temperatures than prior approaches. In preferred implementations, the triple-band arrangement concentrates more than 80 percent, preferably about 82 percent, of the relevant near-field spectral power into the disclosed channels and exceeds a comparable single-band baseline.

In preferred implementations, certain propositions associated with the disclosed architecture are machine-verified or formally proved. Such propositions may include fill-fraction identity propositions, Purcell-enhancement propositions, near-field super-Planckian transfer propositions, band-alignment propositions, triple-band power-advantage propositions, efficiency-stability propositions, and structural-determinacy propositions, including the preferred phi\hat{ }-2 fill-fraction identity. In preferred implementations, these machine-verified or formally proved relationships provide support for determinacy, structural optimality, and internal coherence of preferred disclosed embodiments. Such machine-verification support is distinct from prototype test data and is preferably presented separately from modeled numerical examples.

Accordingly, the disclosed control and operating architecture enables the module 100 to function not merely as a passive near-field converter, but as a dynamically stabilized, channel-selective thermal-to-electrical conversion system that preserves useful performance over practical operating variation.

In preferred implementations, the disclosed module may be fabricated through a sequence of emitter formation, support-structure formation, graphene integration, receiver formation, assembly, and electronics integration. Referring also to FIG. 7, a fabrication flow 700 may include an emitter-deposition stage 702, a pillar-patterning stage 704, a passivation stage 706, a graphene-transfer stage 708, a photovoltaic-growth stage 710, a photovoltaic-thinning stage 712, a bonding stage 714, a vacuum-encapsulation stage 716, and an electronics-integration stage 718.

In preferred implementations, the emitter-deposition stage 702 includes forming the multilayer emitter 104 over the backplane 102. In one preferred implementation, the backplane 102 comprises molybdenum and the emitter 104 comprises alternating titanium nitride layers 106 and aluminum oxide layers 108 deposited in seven periods. In preferred implementations, reactive sputtering, vapor deposition, atomic layer deposition, chemical vapor deposition, or related thin-film formation techniques may be used. In preferred implementations, the layer thicknesses are controlled so that the emitter 104 provides the disclosed triple-band response, including preferred titanium nitride layer thicknesses of about 23 nm and preferred aluminum oxide layer thicknesses of about 37 nm. In preferred process implementations, deposition conditions may further include substrate heating, controlled nitrogen-containing ambient for titanium nitride formation, atomic layer cycling or comparable thickness-control techniques for dielectric formation, and post-deposition thermal treatment sufficient to preserve refractory multilayer stability and target optical response.

In preferred implementations, the pillar-patterning stage 704 includes defining one or more support pillars 116 positioned to maintain the vacuum gap 114. In preferred implementations, lithographic patterning, deposition, lift-off, etching, or combinations thereof may be used to form nanoscale support structures. In preferred implementations, the support pillars 116 are arranged so that the active transfer region remains largely open for radiative coupling while the mechanical spacing function is preserved.

In preferred implementations, the passivation stage 706 includes forming a dielectric coating on the support structures and, where desired, forming or completing the dielectric spacer 110 used between the emitter 104 and the graphene gate 112. In preferred implementations, aluminum oxide or another dielectric material is deposited to reduce electrical shorting, protect interfaces, and preserve the desired nanoscale spacing and electrical isolation conditions.

In preferred implementations, the graphene-transfer stage 708 includes transferring monolayer graphene into position above the emitter 104 and over the dielectric spacer 110. In preferred implementations, the graphene gate 112 may be formed by chemical vapor deposition growth on a donor substrate followed by transfer, cleaning, and patterning. In preferred process implementations, transfer may include use of a temporary carrier film, removal of transfer residue, and patterning sufficient to define an active graphene region and peripheral contact regions. Peripheral contacts may then be defined so that the graphene gate 112 can receive controlled bias during operation.

In preferred implementations, the photovoltaic-growth stage 710 includes forming the receiver stack comprising the top photovoltaic sub-cell 118, the middle photovoltaic sub-cell 122, the bottom photovoltaic sub-cell 126, and tunnel junctions 120 and 124. In preferred implementations, epitaxial growth techniques may be used to form a GaSb/In0.53Ga0.47As/GaInAsSb receiver stack or another suitable channel-matched multijunction structure. In preferred implementations, contact metallization and current-collection structures are also formed in association with the receiver.

In preferred implementations, the photovoltaic-thinning stage 712 reduces receiver thickness where appropriate to support assembly, heat removal, electrical extraction, or gap integration. Mechanical thinning, selective etching, polishing, bonding preparation, or combinations thereof may be used. In preferred implementations, the receiver is then bonded or otherwise mounted in relation to the heat spreader 128 or another cooling structure.

In preferred implementations, the bonding stage 714 aligns the emitter-side structure and receiver-side structure so that the vacuum gap 114 is defined by the support pillars 116 and associated interfaces. In preferred implementations, precision alignment is used so that the graphene gate 112, the emitter 104, and the receiver remain positioned to provide the disclosed near-field and channel-matched behavior. In preferred implementations, the vacuum-encapsulation stage 716 then encloses the assembled structure under vacuum conditions suitable for maintaining the disclosed gap-dependent transport regime.

In preferred implementations, the electronics-integration stage 718 includes connecting output contacts 130, sensing structures, bias circuitry for the graphene gate 112, control circuitry, memory or calibration structures, and optional power-conditioning circuitry. In preferred implementations, the resulting device is configured as an integrated module that can receive thermal input at the emitter side and provide electrical output at the receiver side while dynamically stabilizing spectral alignment during operation.

In one preferred modeled embodiment, the disclosed module is configured as an industrial module having an active area of about 1 cm×1 cm, a preferred emitter temperature of about 950 K, a receiver maintained near about 320 K, a preferred graphene tuning range of about 0.28 eV to about 0.48 eV, and a preferred output on the order of about 7.4 W for the 1 cm×1 cm active area. In preferred implementations, the receiver side is water-cooled or otherwise thermally managed so that useful operating temperature is preserved. In preferred array implementations, multiple such modules may be arranged in a larger panel, subassembly, or array. This preferred industrial module is a preferred modeled embodiment and not the sole definition of the invention.

In some implementations, the disclosed architecture may be varied while preserving the disclosed core module structure. For example, alternative emitter materials, alternative dielectric materials, alternative multijunction receiver materials, alternative gap-support structures, alternative package-level thermal-management structures, alternative cooling structures, and alternative control implementations may be used. Alternative III-V alloy systems, broader bandgap selections, different layer counts, different support-pillar materials, and different package-level arrangements may likewise be used, provided that the resulting module preserves the disclosed core architecture.

In some implementations, optional variable-gap architectures may be used, including microelectromechanical gap-adjustment systems or thermal-switch arrangements. In some implementations, optional patterned-surface features, including chi-lattice patterned-surface features, may also be employed. Such embodiments are technically adjacent alternatives and are subordinate to the core architecture rather than replacements for it.

Referring also to FIG. 12, an alternative configuration FIG. 1200 may include an alternative emitter-material configuration 1202, an alternative receiver-material configuration 1204, an alternative gap configuration 1206, an alternative support structure 1208, and an optional patterned-surface configuration 1210. In preferred implementations, these alternative configurations remain technically adjacent to the disclosed architecture and do not alter the core arrangement of a triple-band emitter, a dynamically biased graphene spectral-control gate, a matched multijunction receiver, and a sub-wavelength vacuum gap.

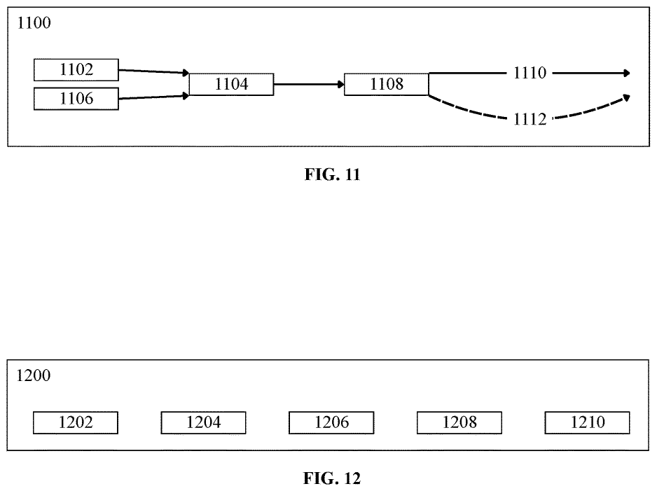

In some implementations, the disclosed module may be deployed in downstream systems including industrial waste-heat recovery systems, radioisotope-powered space systems, micro-combined-heat-and-power systems, portable field power systems, and data-center heat-recovery systems. Referring also to FIG. 11, an industrial system 1100 may include a heat source 1102, a module array 1104, a cooling loop 1106, a power conditioner 1108, an electrical output 1110, and a recovered heat path 1112. In preferred implementations, such deployments preserve the disclosed module architecture as the center of the invention and merely illustrate practical contexts in which the disclosed module may be used.

In preferred modeled examples, a first example may correspond to nominal operation at about 950 K emitter temperature, about 320 K receiver temperature, and about 60 nm gap, yielding total electrical output on the order of about 7.4 W/cm\hat{ }2 and efficiency on the order of about 37 percent. In preferred implementations, such an example may be evaluated by identifying inputs, determining channel-specific enhancement and channel-specific power contributions, summing total electrical output, and determining current, voltage, and efficiency. A second example may correspond to reduced-temperature operation at about 800 K with reduced output and adjusted graphene bias. A third example may correspond to tighter-gap operation at about 40 nm with increased near-field enhancement and increased power density. A fourth example may correspond to wider-gap operation at about 100 nm with reduced power density and modified efficiency behavior. A fifth example may correspond to the preferred industrial module package described above. These examples are worked numerical examples and modeled benchmarks rather than bench-tested prototype demonstrations.

In preferred implementations, formal verification and validation support may be presented separately from the worked numerical examples. Such support may include Lean structures, Lean theorems, fill-fraction identity propositions, enhancement propositions, alignment propositions, stability propositions, triple-band advantage propositions, structural-optimality propositions, determinacy propositions, and internal-coherence propositions. In preferred implementations, these formally supported relationships may be used to support narrower claim families directed to verification-supported embodiments, structural relationships, or control relationships. Such formal verification support is distinct from physical prototype testing and should not be interpreted as a representation of bench-tested reduction to practice unless separate experimental evidence is expressly provided.

The foregoing description sets forth preferred implementations, preferred modeled embodiments, technically adjacent alternatives, downstream deployment examples, numerical examples, and formal-support structures associated with the disclosed architecture. These descriptions are provided to enable and illustrate the invention and should not be interpreted as limiting the invention to the particular implementations expressly described.

What is claimed is:

1. A near-field thermophotovoltaic module comprising: an emitter configured to provide three discrete near-field spectral channels; a graphene spectral-control gate positioned proximate the emitter and configured to be dynamically biased to control modal coupling associated with the three discrete near-field spectral channels; a multijunction photovoltaic receiver positioned opposite the emitter, the multijunction photovoltaic receiver comprising sub-cells corresponding to the three discrete near-field spectral channels; and a sub-wavelength vacuum gap disposed between the emitter and the multijunction photovoltaic receiver, wherein the graphene spectral-control gate is configured to dynamically re-weight modal density to maintain spectral alignment of the three discrete near-field spectral channels with corresponding absorption regions of the multijunction photovoltaic receiver during operation.

2. The module of claim 1, wherein the emitter comprises a hyperbolic metamaterial emitter.

3. The module of claim 2, wherein the emitter comprises alternating metallic and dielectric layers arranged to provide a triple-band spectral response.

4. The module of claim 3, wherein the alternating metallic and dielectric layers are arranged with a metal-to-dielectric fill fraction of phi\hat{ }-2.

5. The module of claim 3, wherein the emitter is configured such that the three discrete near-field spectral channels are centered approximately at 0.65 eV, 0.95 eV, and 1.35 eV.

6. The module of claim 3, wherein the emitter comprises titanium nitride layers and aluminum oxide layers disposed over a molybdenum backplane.

7. The module of claim 6, wherein the emitter comprises seven periods of alternating titanium nitride layers and aluminum oxide layers.

8. The module of claim 7, wherein the titanium nitride layers each have a thickness of about 23 nm and the aluminum oxide layers each have a thickness of about 37 nm.

9. The module of claim 1, wherein the graphene spectral-control gate is separated from the emitter by a dielectric spacer.

10. The module of claim 9, wherein the graphene spectral-control gate is positioned within 10 nm of the emitter.

11. The module of claim 10, wherein the dielectric spacer provides a separation of about 5 nm between the graphene spectral-control gate and the emitter.

12. The module of claim 1, wherein recognition nodes are frequencies at which modal coupling is stationary with respect to the graphene Fermi level such that a self-stabilizing spectral lock is established.

13. The module of claim 1, wherein the multijunction photovoltaic receiver is configured such that each of the three discrete near-field spectral channels has non-zero above-gap overlap with a corresponding sub-cell during operation, and wherein the module further comprises control circuitry configured to update gate bias in closed loop based on sensed emitter temperature information and photovoltaic electrical information to reduce a maximum channel-to-target misalignment across the three discrete near-field spectral channels during emitter drift.

14. The module of claim 13, wherein the multijunction photovoltaic receiver is a triple-junction photovoltaic receiver comprising a GaSb sub-cell having a bandgap of about 0.71 eV, an In0.53Ga0.47As sub-cell having a bandgap of about 0.94 eV, and a GaInAsSb sub-cell having a bandgap of about 1.34 eV.

15. The module of claim 13, wherein the sub-wavelength vacuum gap is about 60 nm, and wherein channel-to-target misalignment is maintained within about plus or minus 10 meV under plus or minus 50 K emitter drift.

16. A method of converting thermal energy to electrical energy, the method comprising: generating, with an emitter, three discrete near-field spectral channels; positioning a multijunction photovoltaic receiver across a sub-wavelength vacuum gap from the emitter; dynamically biasing a graphene spectral-control gate positioned proximate the emitter to maintain spectral alignment of the three discrete near-field spectral channels with corresponding absorption regions of the multijunction photovoltaic receiver during operation; coupling evanescent modes associated with the three discrete near-field spectral channels across the sub-wavelength vacuum gap; and extracting electrical power from the multijunction photovoltaic receiver.

17. The method of claim 16, wherein dynamically biasing the graphene spectral-control gate comprises sensing emitter temperature information and photovoltaic electrical information, determining a current spectral-alignment error, and dynamically re-weighting modal density at each of the three discrete near-field spectral channels under emitter drift to reduce the current spectral-alignment error.

18. The method of claim 16, wherein the multijunction photovoltaic receiver is configured such that each of the three discrete near-field spectral channels has non-zero above-gap overlap with a corresponding sub-cell, and wherein dynamically biasing the graphene spectral-control gate preserves non-zero above-gap overlap for each of the three discrete near-field spectral channels during emitter drift.

19. The method of claim 16, wherein the graphene spectral-control gate is dynamically biased over a Fermi-level range of about 0.28 eV to about 0.48 eV to maintain channel-to-target misalignment within about plus or minus 10 meV under plus or minus 50 K emitter drift.

20. A near-field thermophotovoltaic system comprising: the near-field thermophotovoltaic module of claim 1; a heat source thermally coupled to the emitter of the near-field thermophotovoltaic module; a thermal-management subsystem thermally coupled to the multijunction photovoltaic receiver of the near-field thermophotovoltaic module; control circuitry coupled to the graphene spectral-control gate and configured to update gate bias in closed loop based on sensed emitter temperature information and photovoltaic electrical information to reduce a maximum channel-to-target misalignment across the three discrete near-field spectral channels during emitter drift; and power-conditioning circuitry coupled to electrical output of the near-field thermophotovoltaic module.
